(19) United States
(12) Patent Application Publication
(10) Pub. No.: US 2026/0173529 A1
(43) Pub. Date: Jun. 18, 2026

(54) DISPLAY SUBSTRATE, DISPLAY PANEL AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Dongsheng JING, Beijing (CN); Keke GU, Beijing (CN); Jianfeng LIU, Beijing (CN); Xuefang CHEN, Beijing (CN); Xing ZHANG, Beijing (CN); Yang HE, Beijing (CN); Ying CHEN, Beijing (CN); Chenchen FAN, Beijing (CN); Yi WANG, Beijing (CN)

(73) Assignees: CHONGQING BOE OPTOELECTRONICS TECHNOLOGY CO., LTD., Chongqing (CN); BOE TECHNOLOGY GROUP CO., LTD., Beijing (CN)

(21) Appl. No.: 18/711,829

(22) PCT Filed: Apr. 26, 2023
(86) PCT No.: PCT/CN2023/090967

§ 371 Date: May 20, 2024

(51) Int. Cl. H10D 86/40; G09G 3/30; H10D 86/60

(52) U.S. Cl. CPC H10D 86/441; G09G 3/30; H10D 86/60; G09G 2330/12

(57) ABSTRACT

A display substrate, a display panel and a display device are provided. The display substrate has a display area and a peripheral area, the display substrate includes a test structure, a transmission line and a driving circuit; the test structure includes an electrical test structure and a first connection portion; the electrical test structure is arranged on a side of the transmission line away from the display area; the electrical test structure is configured to transmit an electrical test signal to the driving circuit; the driving circuit is configured to provide a driving signal; the transmission line is a signal transmission line between the driving integrated circuit and the driving circuit; the electrical test structure is electrically connected to the transmission line through the first connection portion; the transmission line and the first connection portion are located in different conductive layers.

### TECHNICAL FIELD

The present disclosure relates to the field of display technology, in particular to a display substrate, a display panel and a display device.

### BACKGROUND

In the related art, the preparation of a display panel includes an array substrate process, a color filter substrate process, and a cell forming process of the array substrate and the color filter substrate. After the array substrate and the color filter substrate are aligned, the entire film substrate is cut into individual panels, and Electrical Test (ET) process is performed on the cut individual panels. The ET test process loads test electrical signals into the individual panels through the test pads on the array substrate to detect defects on the individual panels. After the ET testing process, defective products are eliminated, and good products are processed to form a display panel. In the display panel, one end of the test pad is connected to the driving integrated circuit in the flexible circuit board (FPC), and the other end is connected to the GOA circuit inside the display panel, which plays the role of transmitting driving signals.

Since the GOA circuit is made on the base substrate by the Array process, in the actual layout, long metal traces are inevitably present on the transmission path of the driving signal, and the test pad has a large area and is easy to accumulate charges. When static electricity occurs, the static electricity will directly enter the interior of the display panel through the test pad, causing the components of the driving circuit inside the display panel to burn out, resulting in abnormal display of the display panel.

### SUMMARY

In one aspect, the present disclosure provides in some embodiments a display substrate having a display area and a peripheral area, wherein the display substrate includes a test structure, a transmission line and a driving circuit; the test structure includes an electrical test structure and a first connection portion; the electrical test structure is arranged on a side of the transmission line away from the display area; the electrical test structure is configured to transmit an electrical test signal to the driving circuit; the driving circuit is configured to provide a driving signal; the transmission line is a signal transmission line between a driving integrated circuit and the driving circuit; the electrical test structure is electrically connected to the transmission line through the first connection portion; the transmission line and the first connection portion are located in different conductive layers.

Optionally, a resistivity of the first connection portion is greater than a resistivity of the transmission line.

Optionally, the electrical test structure includes a test transistor; the test transistor includes a gate electrode, a first electrode and a second electrode; the gate electrode is electrically connected to the first electrode, and the second electrode is electrically connected to the transmission line through the first connection portion.

Optionally, the transmission line is a single-layer line, and the first connection portion is a single-layer connection portion.

Optionally, the electrical test structure includes a test pad; the test pad is electrically connected to the first connection portion.

Optionally, the test structure further includes a first electrostatic discharge structure; the first connection portion is electrically connected to the test pad through the first electrostatic discharge structure; the first electrostatic discharge structure includes a plurality of first via holes.

Optionally, the test structure further includes a second electrostatic discharge structure; the first connection portion is electrically connected to the transmission line through the second electrostatic discharge structure; the second electrostatic discharge structure includes a plurality of second via holes.

Optionally, the first connection portion is electrically connected to the test pad through a first via hole, and the first connection portion is electrically connected to the transmission line through a second via hole; an aperture of the first via hole is smaller than an aperture of the second via hole.

Optionally, a ratio of the aperture of the first via hole to the aperture of the second via hole is greater than or equal to 1/1.8 and less than or equal to 1/1.2.

Optionally, the electrical test structure further includes a test pad; the gate electrode of the test transistor and the test pad form an integral structure; the test transistor is configured to transmit an electrical test signal to the transmission line.

Optionally, the electrical test structure further includes a test pad; the test pad is configured to transmit an electrical test signal to the test transistor; the gate electrode of the test transistor and the test pad are separate structures; the first electrode is electrically connected to the test pad.

Optionally, a resistivity of the first connection portion is greater than a resistivity of the transmission line; the test structure further includes a third electrostatic discharge structure; the first connection portion is electrically connected to the second electrode through the third electrostatic discharge structure; the third electrostatic discharge structure includes a plurality of third via holes.

Optionally, the test structure further includes a fourth electrostatic discharge structure; the first connection portion is electrically connected to the transmission line through the fourth electrostatic discharge structure; the fourth electrostatic discharge structure includes a plurality of fourth via holes.

Optionally, a resistivity of the first connection portion is greater than a resistivity of the transmission line, and the first connection portion is electrically connected to the second electrode through a third via hole, and the first connection portion is electrically connected to the transmission line through a fourth via hole; an aperture of the third via hole is smaller than an aperture of the fourth via hole.

Optionally, a ratio of the aperture of the third via hole to the aperture of the fourth via hole is greater than or equal to 1/1.8 and less than or equal to 1/1.2.

Optionally, a thickness of the first connection portion is smaller than a thickness of the transmission line.

Optionally, the first connection portion is located in a first conductive layer, and the first conductive layer is made of ITO.

Optionally, the test transistor is an oxide transistor, and a width-to-length ratio of the test transistor is less than or equal to 2.

Optionally, the test transistor is an amorphous silicon transistor, and a width-to-length ratio of the test transistor is less than or equal to 100/3.6.

Optionally, the test pad and the transmission line are located in a same conductive layer, and the transmission line and the first connection portion are located in different conductive layers.

Optionally, the first connection portion, the first electrode and the second electrode are located in a same conductive layer, and the gate electrode and the transmission line are located in a same conductive layer, the first connection portion and the transmission line are located in different conductive layers.

Optionally, the first electrode and the second electrode are located in a same conductive layer; the first electrode includes a first body portion and at least one first extension portion that are electrically connected to each other, and the second electrode includes a second body portion and at least one second extension portion; the first body portion and the second body portion both extend along a first direction, and the first extension portion and the second extension portion both extend along a second direction; the first direction intersects the second direction.

Optionally, the first electrode includes at least two first extension portions, and the at least two first extension portions are arranged along the first direction; the second electrode includes at least two second extension portions, the at least two second extension portions are arranged along the first direction; at least part of at least one second extension portion is arranged between two adjacent first extension portions.

Optionally, the first electrode and the second electrode are located in a same conductive layer, the gate electrode and the transmission line are located in a same conductive layer, and the first connection portion and the first electrode are located in different conductive layers, and the first connection portion and the transmission line are located in different conductive layers.

Optionally, the test pad, the first electrode, the second electrode and the first connection portion are located in a same conductive layer, and the gate electrode and the transmission line are located in a same conductive layer, and the first connection portion and the transmission line are located in different conductive layers.

Optionally, the test pad, the first electrode and the second electrode are located in a same conductive layer, and the gate electrode and the transmission line are located in a same conductive layer, the first connection portion and the test pad are located in different conductive layers, and the first connection portion and the transmission line are located in different conductive layers.

In a second aspect, an embodiment of the present disclosure provides a display panel, including the driving integrated circuit and the display substrate; the driving integrated circuit is configured to provide a signal to the driving circuit.

In a second aspect, an embodiment of the present disclosure provides a display device, including the display panel.

### BRIEF DESCRIPTION OF THE DRAWINGS

FIGS. 1A and 1B are structural diagrams of a display substrate according to at least one embodiment of the present disclosure;

FIG. 2 is a structural diagram of a display substrate according to at least one embodiment of the present disclosure;

FIG. 3 is a layout diagram of the first metal layer in FIG. 1A;

FIG. 4 is a layout diagram of the first conductive layer in FIG. 1A;

FIG. 5 is a cross-sectional view of A-A′ in FIG. 1A;

FIG. 6 is a structural diagram of a display substrate according to at least one embodiment of the present disclosure;

FIG. 7 is a layout diagram of the first metal layer in FIG. 6;

FIGS. 8A and 8B are layout diagrams of the second metal layer in FIG. 6;

FIG. 9 is a layout diagram of the semiconductor layer in FIG. 6;

FIG. 10 is a layout diagram of the first conductive layer in FIG. 6;

FIG. 11 is a waveform diagram of the first noise reduction voltage signal VDDO and the second noise reduction voltage signal VDDE;

FIG. 12 is a structural diagram of a display substrate according to at least one embodiment of the present disclosure;

FIG. 13 is a layout diagram of the first metal layer in FIG. 12;

FIG. 14 is a layout diagram of the source-drain electrode layer in FIG. 12;

FIG. 15 is a layout diagram of the semiconductor layer in FIG. 12;

FIG. 16 is a layout diagram of the first conductive layer in FIG. 12;

FIGS. 17A and 17B are structural diagrams of a display substrate according to at least one embodiment of the present disclosure;

FIG. 18 is a layout diagram of the first metal layer in FIG. 17A;

FIG. 19 is a layout diagram of the source-drain electrode layer in FIG. 17A;

FIG. 20 is a layout diagram of the semiconductor layer in FIG. 17A;

FIG. 21 is a layout diagram of the first conductive layer in FIG. 17A;

FIG. 22 is a B-B′ cross-sectional view in FIG. 17A;

FIG. 23 is a structural diagram of a display substrate according to at least one embodiment of the present disclosure;

FIG. 24 is a layout diagram of the first metal layer in FIG. 23;

FIGS. 25A and 25B are layout diagrams of the second metal layer in FIG. 23;

FIG. 26 is a layout diagram of the semiconductor layer in FIG. 23;

FIG. 27 is a layout diagram of the first conductive layer in FIG. 23;

FIG. 28 is a schematic diagram of a test structure included in a display panel according to at least one embodiment of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some of the embodiments of the present disclosure, rather than all of the embodiments. Based on the embodiments in the present disclosure, all other embodiments obtained by those of ordinary skill in the art without making creative efforts fall within the scope of protection of the present disclosure.

The transistors used in all embodiments of the present disclosure may be thin film transistors, field effect transistors, or other devices with the same characteristics. In the embodiment of the present disclosure, in order to distinguish the two electrodes of the transistor except the gate electrode, one electrode is called the first electrode and the other electrode is called the second electrode.

In actual operation, when the transistor is a thin film transistor or a field effect transistor, the first electrode may be a drain electrode, and the second electrode may be a source electrode; or, the first electrode may be a source electrode, the second electrode may be a drain electrode.

The display substrate according to the embodiment of the present disclosure has a display area and a peripheral area; the display substrate includes a test structure, a transmission line and a driving circuit; the test structure includes an electrical test structure and a first connection portion;

The electrical test structure is arranged on a side of the transmission line away from the display area; the electrical test structure is configured to transmit an electrical test signal to the driving circuit; the driving circuit is configured to provide a driving signal;

The transmission line is a signal transmission line between the driving integrated circuit and the driving circuit; the electrical test structure is electrically connected to the transmission line through the first connection portion;

The transmission line and the first connection portion are located in different conductive layers.

Embodiments of the present disclosure provide a test structure that can prevent Electro-Static discharge (ESD). The electrical test structure can be arranged on a side of the transmission line away from the display area without increasing additional development costs and processes. On one side, it can not only ensure normal electrical testing, but also realize the electrostatic protection function.

Optionally, the resistivity of the first connection portion may be greater than the resistivity of the transmission line. In at least one embodiment of the present disclosure, the electrical test structure can be electrically connected to the transmission line through a first connection portion, and the resistivity of the first connection portion is greater than the resistivity of the transmission line, so that when ESD is passing through, the first connection portion is burned out, thereby protecting the driving circuit inside the display panel.

Optionally, the electrical test structure may include a test transistor; the test transistor includes a gate electrode, a first electrode and a second electrode; the gate electrode is electrically connected to the first electrode, and the second electrode is electrically connected to the transmission line through the first connection portion.

In specific implementation, the electrical test structure may include a diode-connected test transistor. The second electrode of the test transistor is electrically connected to the transmission line through the first connection portion. The diode-connected test transistor may be used to protect the driving circuit inside the display panel by using the characteristic the transistor is easy to burn out when subject to the ESD impacts.

In at least one embodiment of the present disclosure, the driving circuit may be a Gate On Array (GOA, gate driving circuit arranged on the array substrate) circuit, configured to provide driving signals for pixel circuits included in the display substrate.

In at least one embodiment of the present disclosure, the transmission line may be a single-layer line, and the first connection portion may be a single-layer connection portion.

In specific implementation, all parts of the transmission line may be located in a same conductive layer, and all parts of the first connection portion may be located in the same conductive layer, so as to simplify the structure.

In at least one embodiment of the present disclosure, the electrical test structure includes a test pad;

The resistivity of the first connection portion is greater than the resistivity of the transmission line, and the test pad is electrically connected to the first connection portion.

In specific implementation, the electrical test structure may include a test pad, the resistivity of the first connection portion is greater than the resistivity of the transmission line, and the test pad is electrically connected to the first connection portion.

In at least one embodiment of the present disclosure, the test structure may further include a first electrostatic discharge structure;

The first connection portion is electrically connected to the test pad through the first electrostatic discharge structure;

The first electrostatic discharge structure may include a plurality of first via holes.

In specific implementation, the first connection portion can be electrically connected to the test pad through a plurality of first via holes included in the first electrostatic discharge structure. By using a plurality of first via holes, compared with using a single first via hole, better electrostatic protection can be provided.

Optionally, the test structure may also include a second electrostatic discharge structure;

The first connection portion is electrically connected to the transmission line through the second electrostatic discharge structure;

The second electrostatic discharge structure includes a plurality of second via holes.

In specific implementation, the first connection portion can be electrically connected to the transmission line through a plurality of second via holes included in the second electrostatic discharge structure. By using a plurality of second via holes, compared with using a single second via hole, better electrostatic protection can be provided.

In at least one embodiment of the present disclosure, the first connection portion is electrically connected to the test pad through a first via hole, and the first connection portion is electrically connected to the transmission line through a second via hole;

An aperture of the first via hole is smaller than an aperture of the second via hole.

In specific implementation, the aperture of the first via hole close to the test pad can be set to be smaller than the aperture of the second via hole. The smaller the aperture is, the greater the resistance is. When a large current passes through, the first via hole has firstly burned out, thus preventing ESD from entering the interior of the display panel when ESD occurs, thus playing an ESD protection role.

Optionally, a ratio of the aperture of the first via hole to the aperture of the second via hole is greater than or equal to 1/1.8 and less than or equal to 1/1.2.

Optionally, the first via hole may be greater than or equal to 5 μm and less than or equal to 15 μm, and the second via hole may be greater than or equal to 15 μm and less than or equal to 40 μm, but is not limited thereto.

Optionally, the first connection portion is located in the first conductive layer, and the first conductive layer is made of ITO.

In at least one embodiment of the present disclosure, the thickness of the first connection portion is smaller than the thickness of the transmission line, so that when ESD occurs, the first connection portion is burned out preferentially.

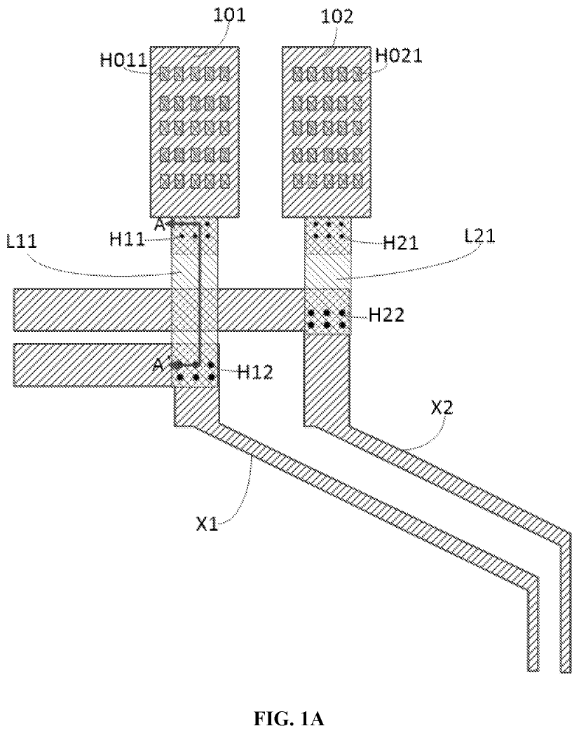

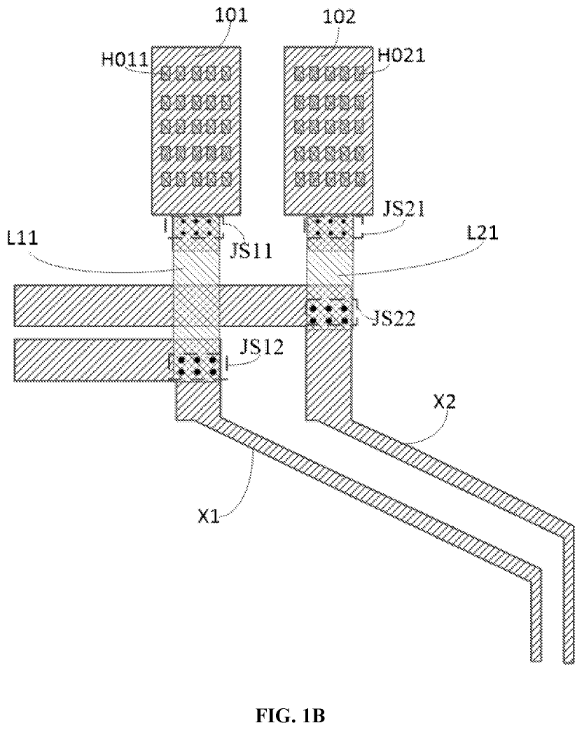

As shown in FIG. 1A, in the display substrate according to at least one embodiment of the present disclosure, the test structure includes an electrical test structure and a first first connection portion L11 and a second first connection portion L21; the test structure includes a first test pad 101 and a second test pad 102;

In FIG. 1A, the one labeled X1 is the first transmission line, and the one labeled X2 is the second transmission line;

The first test pad 101 is arranged on a side of the first transmission line X1 and the second transmission line X2 away from the display area; the second test pad 102 is arranged on a side of the first transmission line X1 and the second transmission line X2 away from the display area; the first test pad 101 and the second test pad 102 are used to transmit electrical test signals to the driving circuit;

The first test pad 101 is electrically connected to the first first connection portion L11 through the first first via hole H11, and the first first connection portion L11 is connected to the first transmission line X1 through the first second via hole H12.

The second test pad 102 is electrically connected to the second first connection portion L21 through the second first via hole H21, and the second first connection portion L21 is electrically connected to the second transmission line X2 through the second second via hole H22;

The resistivity of the first first connection portion L11 is greater than the resistivity of the first transmission line X1; the resistivity of the second first connection portion L21 is greater than the resistivity of the second transmission line X2;

The first transmission line X1 and the second transmission line X2 are signal transmission lines between the driving integrated circuit and the driving circuit.

In at least one embodiment of the present disclosure, the resistance of L11 may be greater than the resistance of X1, and the resistance of L21 may be greater than the resistance of X2.

In FIG. 1B, the one labeled JS11 is a first first electrostatic release structure, the one labeled JS21 is a second first electrostatic release structure, the one labeled JS12 is a first second electrostatic release structure, and the one labeled JS22 is a second second electrostatic release structure;

The first first electrostatic discharge structure JS11 includes six first via holes, and the second first electrostatic discharge structure JS21 includes six first via holes;

The first second electrostatic discharge structure JS12 includes six second via holes, and the second second electrostatic discharge structure JS22 includes six second via holes.

In at least one embodiment shown in FIGS. 1A to 5, each first electrostatic discharge structure includes six first via holes, and each second electrostatic discharge structure includes six second via holes, so as to increase the number of via holes to provide good electrostatic protection.

In at least one embodiment shown in FIG. 1A to FIG. 5, the first transmission line X1, the second transmission line X2, the first test pad 101 and the second test pad 102 are all located in the first metal layer, the first first connection portion L11 and the second first connection portion L21 are both located in the first conductive layer; a first insulating layer is used to separate the first metal layer and the first insulating layer, a via hole is formed on the first insulating layer so that the first conductive layer is lapped on the first metal layer to achieve electrical connection between the test pad and the transmission line;

The first conductive layer may be an Indium Tin Oxide (ITO) layer, and the first metal layer may be a gate electrode layer, but is not limited thereto.

In at least one embodiment shown in FIGS. 1A-5, the thickness of the first first connection portion L11 is less than the thickness of the first transmission line X1, and the thickness of the second first connection portion L21 is less than the thickness of the second transmission line X2.

In at least one embodiment of the present disclosure, the thickness of the ITO layer may be greater than or equal to 600 angstroms and less than or equal to 1500 angstroms, and the thickness of the gate electrode layer may be greater than or equal to 2500 angstroms and less than or equal to 4000 angstroms, but not limited thereto.

As shown in FIG. 1A, the aperture of the first first via hole H11 is smaller than the aperture of the first second via hole H12, and the aperture of the second first via hole H21 is smaller than the aperture of the second second via hole H22.

In at least one embodiment shown in FIGS. 1A-5, the first test pad 101 is electrically connected to the first first conductive structure J11 located in the first conductive layer through the first first connection via hole H011, the second test pad 102 is electrically connected to the second first conductive structure J21 located in the first conductive layer through the second first connection via hole H021;

When performing the electrical testing, the electrical test signal can be transmitted to the first test pad 101 through the first first conductive structure J11 and the first first connection via hole H011 through a probe, and then transmitted to driving circuit, and the electrical test signal can be transmitted to the second test pad 102 through the second first conductive structure J21 and the second first connection via hole H021 through the probe, and then transmitted to the driving circuit.

Optionally, the aperture of the first first connection via hole H01 may be greater than or equal to 30 μm and less than or equal to 80 μm, and the aperture of the second first connection via hole H021 may be greater than or equal to 30 μm but less than or equal to 80 μm. For example, the aperture of the first first connection via hole H011 may be 40 μm, and the aperture of the second first connection via hole H021 may be 40 μm.

In at least one embodiment shown in FIG. 1A to FIG. 5, when ESD occurs, the ESD first passes through the first first via hole H11 and the second first via hole H21, and the first first via hole H11, the second first via hole H21, the first first connection portion L11 and the second first connection portion L21 are burned out first to prevent ESD from entering the interior of the display panel and play a role in electrostatic protection.

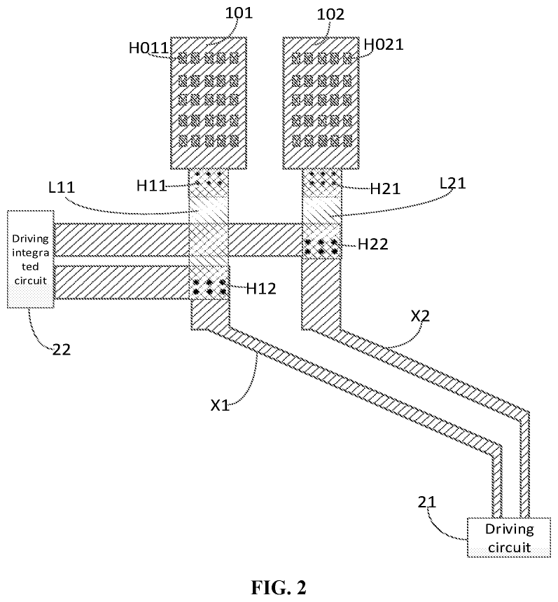

As shown in FIG. 2, based on at least one embodiment shown in FIG. 1A, a driving circuit 21 and a driving integrated circuit 22 are added;

The first transmission line X1 and the second transmission line X2 are signal transmission lines between the driving integrated circuit 22 and the driving circuit 21.

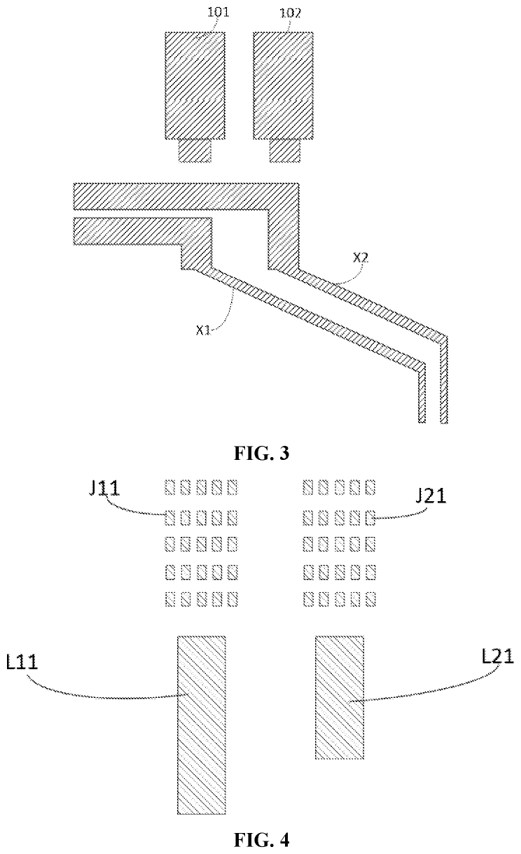

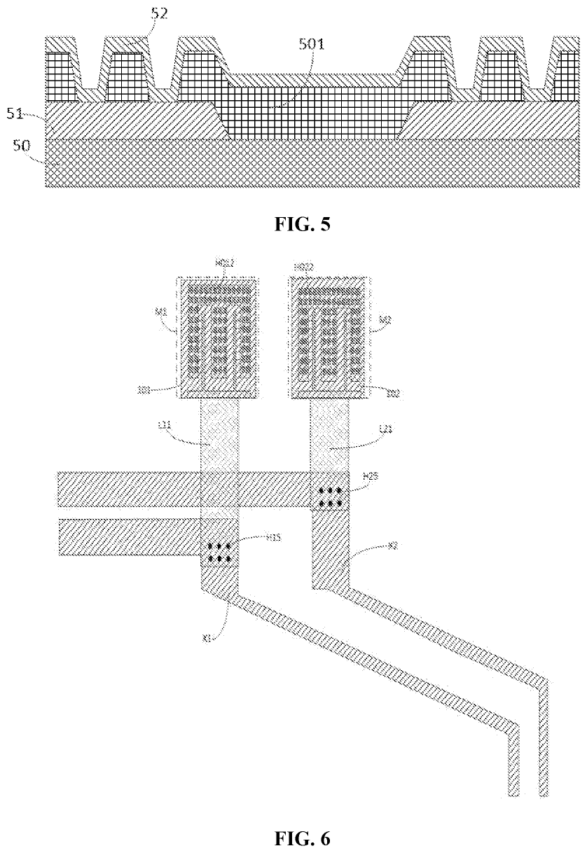

FIG. 3 is a layout diagram of the first metal layer in FIG. 1A, FIG. 4 is a layout diagram of the first conductive layer in FIG. 1A, and FIG. 5 is a cross-sectional view of A-A′ in FIG. 1A.

In FIGS. 5, 50 is the base, 51 is the first metal layer, 52 is the first conductive layer, and 501 is the first insulating layer.

In at least one embodiment of the present disclosure, the electrical test structure includes a test transistor; the electrical test structure further includes a test pad;

The gate electrode of the test transistor and the test pad have an integrated structure;

The test transistor is used to transmit electrical test signals to the transmission lines.

Optionally, when the electrical test structure includes a test transistor,

The test transistor is an oxide transistor, and a width-to-length ratio of the test transistor is less than or equal to 2; or,

The test transistor is an amorphous silicon transistor, and the width-to-length ratio of the test transistor is less than or equal to 100/3.6.

In specific implementation, the width-to-length ratio of the test transistor can be equivalent to or smaller than the width-to-length ratio of a TFT with the smallest width-to-length ratio in the GOA circuit. The specific size is set according to the GOA circuit design.

As shown in FIGS. 6-10, in the display substrate according to at least one embodiment of the present disclosure, the test structure includes a first transmission line X1, a second transmission line X2, an electrical test structure, a first first connection portion L11 and a second first connection portion L21; the electrical test structure includes a first test transistor M1 and a second test transistor M2; the first test transistor M1 is arranged on a side of the first transmission line X1 and the second transmission line X2 away from the display area, and the second test transistor M2 is provided on the side of the first transmission line X1 and the second transmission line X2 away from the display area;

The first transmission line X1 and the second transmission line X2 are signal transmission lines between the driving integrated circuit and the driving circuit;

The first test transistor M1 includes a gate electrode, a first electrode and a second electrode; the gate electrode of the first test transistor M1 is electrically connected to the first electrode S1 of the first test transistor M1, and the second electrode D1 of the first test transistor M1 is electrically connected to the first transmission line X1 through the first first connection portion L11;

The second test transistor M2 includes a gate electrode, a first electrode and a second electrode; the gate electrode of the second test transistor M2 is electrically connected to the first electrode S2 of the second test transistor M2, and the second electrode D2 of the second test transistor M2 is electrically connected to the second transmission line X2 through the second first connection portion L21;

As shown in FIG. 7, the gate electrode of the first test transistor M1 and the first test pad 101 are an integral structure, and the gate electrode of the second test transistor M2 and the second test pad 102 are an integral structure;

The first test transistor M1 is used to transmit the electrical test signal to the first transmission line X1, and the second test transistor M2 is used to transmit the electrical test signal to the second transmission line X2.

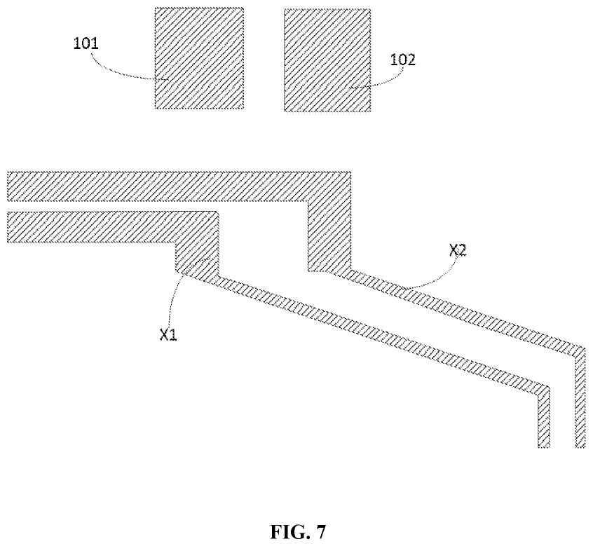

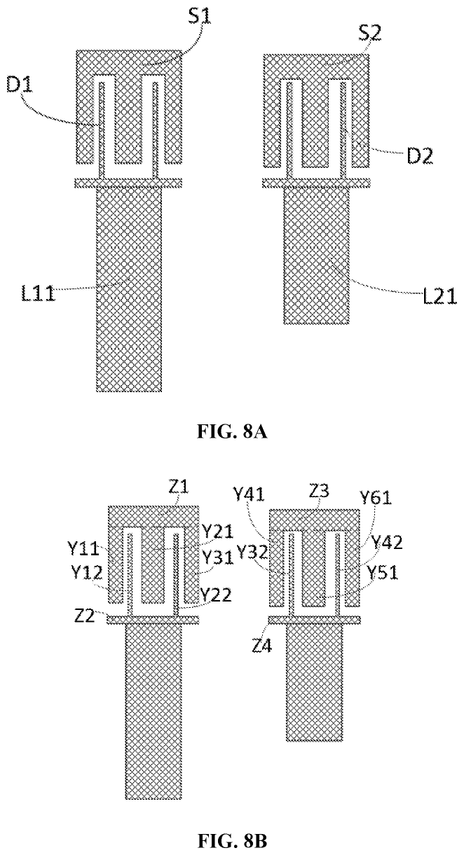

In FIG. 8A, the one labeled S1 is the first electrode of M1, the one labeled D1 is the second electrode of M1, the one labeled S2 is the first electrode of M2, and the one labeled D2 is the second electrode of M2.

In at least one embodiment shown in FIGS. 6 to 10, the first transmission line X1, the second transmission line X2, the first test pad 101 and the second test pad 102 are all located at in the first metal layer, the first electrode S1 of the first test transistor M1, the second electrode D1 of the first test transistor M1, the first electrode S2 of the second test transistor M2 and the second electrode D2 of the second test transistor M2 are all located in the second metal layer, and the first first connection portion L11 and the second first connection portion L21 are located in the second metal layer;

The first metal layer may be a gate electrode layer, and the second metal layer may be a source-drain electrode layer, but is not limited thereto.

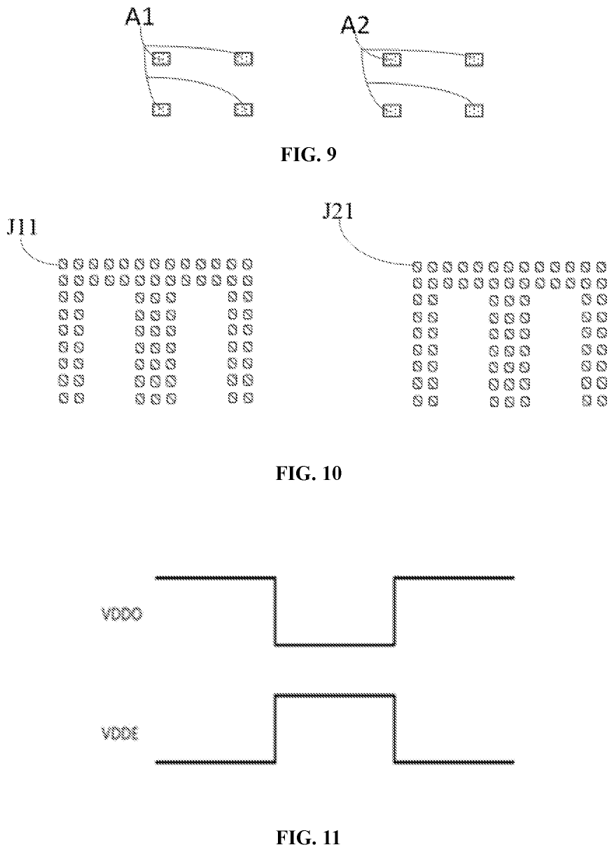

FIG. 7 is a layout diagram of the first metal layer in FIG. 6. FIGS. 8A and 8B are layout diagrams of the second metal layer in FIG. 6. FIG. 9 is a layout diagram of the semiconductor layer in FIG. 6. FIG. 10 is a layout diagram of the first conductive layer in FIG. 6.

In FIG. 9, the one labeled A1 is the active pattern of M1, and the one labeled A2 is the active pattern of M2.

As shown in FIGS. 6 to 10, the first first connection portion L11 is electrically connected to the first transmission line X1 through the first fifth via hole H15; the second first connection portion L21 is electrically connected to the second transmission line X2 through the second fifth via hole H25;

The first test pad 101 is electrically connected to the first electrode S1 of the first test transistor M1 and the first first conductive structure J11 located in the first conductive layer through the first second connection via hole H012; the second test pad 102 is respectively electrically connected to the first electrode S2 of the second test transistor M2 and the second first conductive structure located in the first conductive layer through the second second connection via hole H022.

The aperture of the first second connection via hole H012 may be greater than or equal to 30 μm and less than or equal to 80 μm, and the aperture of the second second connection via hole H022 may be greater than or equal to 30 μm and less than or equal to 80 μm, for example, the first second connection via hole H012 may have an aperture of 40 μm, and the second second connection via hole H022 may have an aperture of 40 μm.

In at least one embodiment shown in FIG. 6, the first test transistor M1 and the second test transistor M2 may be n-type transistors, but are not limited thereto.

In at least one embodiment shown in FIG. 6, the electrical test structure includes a diode-connected first test transistor M1 and a diode-connected second test transistor M2, and the gate electrode of the first test transistor M1 is multiplexed as the first test pad 101, the gate electrode of the second test transistor M2 is multiplexed as the second test pad 102. When ESD passes through, the first test transistor M1 and the second test transistor M2 are burned out preferentially, to form a short circuit, thereby protecting the GOA circuit.

In at least one embodiment shown in FIG. 6, the first test pad 101 may be used to transmit a first noise reduction voltage signal VDDO, and the second test pad 102 may be used to transmit a second noise reduction voltage signal VDDE;

As shown in FIG. 11, the first noise reduction voltage signal VDDO may be inverted in phase with the second noise reduction voltage signal VDDE. When the potential of VDDO is a high voltage, the potential of VDDE may be a low voltage. When the potential of VDDO is a low voltage, the potential of VDDE is a high voltage; for example, every 2 s, the potential of VDDO jumps from the first voltage to the second voltage, and the potential of VDDE jumps from the second voltage to the first voltage; the first voltage is a high voltage or a low voltage, and the second voltage is a low voltage or a high voltage.

In specific implementation, when the potential of VDDO is a high voltage, the first test transistor M1 is turned on and VDDO is transmitted into the display panel. At this time, the potential of VDDE is a low voltage, the second test transistor M2 is turned off, and the GOA circuit operates normally; when the potential of VDDO is a low voltage, the first test transistor M1 is turned off. At this time, the potential of VDDE is a high voltage, the second test transistor M2 is turned on, and VDDE is transmitted into the display panel, and the GOA circuit works normally;

When ESD occurs, the ESD first passes through the first test transistor M1 and the second test transistor M2. The first test transistor M1 and the second test transistor M2 are burned out, thereby protecting the GOA circuit and preventing the problem of conductorization of transistors included in the noise reduction unit caused by ESD impact, optimizing the display product design and improving the display product life.

In at least one embodiment of the present disclosure, the noise reduction unit may include a first noise reduction transistor and a second noise reduction transistor;
a gate electrode of the first noise reduction transistor and a first electrode of the first noise reduction transistor may both be connected to VDDO, and a second electrode of the first noise reduction transistor may be electrically connected to the pull-down node;
a gate electrode of the second noise reduction transistor and a first electrode of the second noise reduction transistor may both be connected to VDDE, and a second electrode of the second noise reduction transistor may be electrically connected to the pull-down node.

At least one embodiment of the present disclosure not only has a protective effect on signals connected to the noise reduction unit, but also has a protective effect on other signals.

In at least one embodiment of the present disclosure, the first electrode and the second electrode are located in the same conductive layer;

The first electrode includes a first body portion and at least one first extension portion that are electrically connected to each other, and the second electrode includes a second body portion and at least one second extension portion;

The first body portion and the second body portion both extend along a first direction, and the first extension portion and the second extension portion both extend along the second direction;

The first direction intersects the second direction.

Optionally, the first electrode includes at least two first extension portions, and the at least two first extension portions are arranged along the first direction;

The second electrode includes at least two second extension portions, the at least two second extension portions are arranged along the first direction;

At least part of at least one second extension portion is arranged between two adjacent first extension portions.

In at least one embodiment of the present disclosure, the first direction may be a horizontal direction, and the second direction may be a vertical direction, but is not limited thereto.

As shown in FIGS. 6 to 10, the first electrode of the first test transistor M1 is in the shape of E, and the second electrode of the first test transistor M1 is in the shape of π; the first electrode of the second test transistor M2 is in the shape of E, and the second electrode of the second test transistor M2 is in the shape of π;

As shown in FIGS. 8A and 8B, the first electrode S1 of the first test transistor M1 includes a first body portion Z1 extending in the horizontal direction and a first first extension portion Y11 extending in the vertical direction, the second first extension portion Y21 extending in the vertical direction and the third first extension portion Y31 extending in the vertical direction that are electrically connected to each other;

Y11, Y21 and Y31 are arranged in the horizontal direction;

The second electrode D1 of the first test transistor M1 includes a second body portion Z2 extending in the horizontal direction, a first second extension portion Y12 extending in the vertical direction, and a second second extension portion Y22 extending in the vertical direction that are electrically connected to each other;

Y12 and Y22 extend in the horizontal direction;

Y12 is set between Y11 and Y21, Y12 is set between Y21 and Y31;

The second electrode S2 of the second test transistor M1 includes a third body portion Z3 extending in the horizontal direction, a fourth first extension portion Y41 extending in the vertical direction, a fifth first extension portion Y51 extending in the vertical direction and a sixth first extension portion Y61 extending in the vertical direction that are electrically connected to each other;

Y41, Y51 and Y61 are arranged in the horizontal direction;

The second electrode D2 of the second test transistor M2 includes a fourth body portion Z4 extending in the horizontal direction, a third second extension portion Y32 extending in the vertical direction, and a fourth second extension portion Y42 extending in the vertical direction that are electrically connected to each other;

Y32 and Y42 extend in the horizontal direction;

Y32 is set between Y41 and Y51, and Y42 is set between Y51 and Y61.

In at least one embodiment of the present disclosure, when the electrical test structure includes a test transistor, the electrical test structure further includes a test pad; the test pad is used to transmit an electrical test signal to the test transistor; the gate electrode of the test transistor and the test pad are separate structures;

The first electrode is electrically connected to the test pad.

In specific implementation, the electrical test structure may include a test transistor, and the test transistor may be arranged between the test pad and the first connection structure.

Optionally, when the electrical test structure includes a test transistor,

The test transistor is an oxide transistor, and the width-to-length ratio of the test transistor is less than or equal to 2; or,

The test transistor is an amorphous silicon transistor, and the width-to-length ratio of the test transistor is less than or equal to 100/3.6.

In specific implementation, the width-to-length ratio of the test transistor can be equivalent to or smaller than the width-to-length ratio of a TFT with the smallest width-to-length ratio in the GOA circuit. The specific size is set according to the GOA circuit design.

In at least one embodiment of the display substrate shown in FIGS. 6-10, the first test transistor M1 and the second test transistor M2 may be oxide transistors, and the width-to-length ratio of M1 and the width-to-length ratio of M2 are both less than 2.

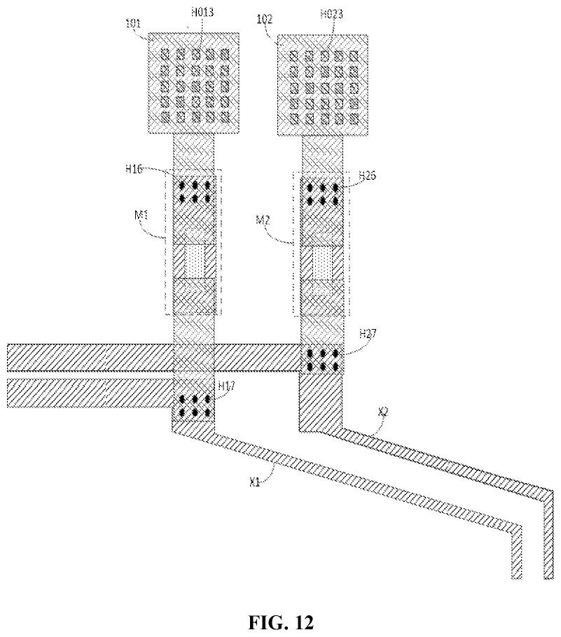

As shown in FIGS. 12-16, in the display substrate according to at least one embodiment of the present disclosure, the test structure includes an electrical test structure, a first first connection portion L11 and a second first connection portion L21; The electrical test structure includes a first test transistor M1, a second test transistor M2, a first test pad 101 and a test pad 102; the first test transistor M1 is provided on a side of the first transmission line X1 and the second transmission line X2 away from the display area; the second test transistor M2 is provided on the side of the first transmission line X1 and the second transmission line X2 away from the display area;

The first transmission line X1 and the second transmission line X2 are signal transmission lines between the driving integrated circuit and the driving circuit;

The first test transistor M1 includes a gate electrode, a first electrode and a second electrode; the gate electrode G1 of the first test transistor M1 is electrically connected to the first electrode S1 of the first test transistor M1, and the second electrode D1 of the first test transistor M1 is electrically connected to the first transmission line X1 through the first first connection portion L11;

The second test transistor M2 includes a gate electrode, a first electrode and a second electrode; the gate electrode G2 of the second test transistor M2 is electrically connected to the first electrode S2 of the second test transistor M2, and the second electrode D2 of the second test transistor M2 is electrically connected to the second transmission line X2 through the second first connection portion L21.

In at least one embodiment of the display substrate shown in FIGS. 12 to 16, the first transmission line X1, the second transmission line X2, the gate electrode G1 of the first test transistor M1 and the gate electrode G2 of the second test transistor M2 may be located in the first metal layer, the first test pad 101, the second test pad 102, the first electrode S1 of the first test transistor M1, the second electrode D1 of the first test transistor M1, the first electrode S2 of the second test transistor M2, the second electrode D2 of the second test transistor M2, the first first connection portion L11 and the second first connection portion L21 are all located in the second metal layer;

The first metal layer may be an electrode metal layer, and the second metal layer may be a source-drain electrode layer.

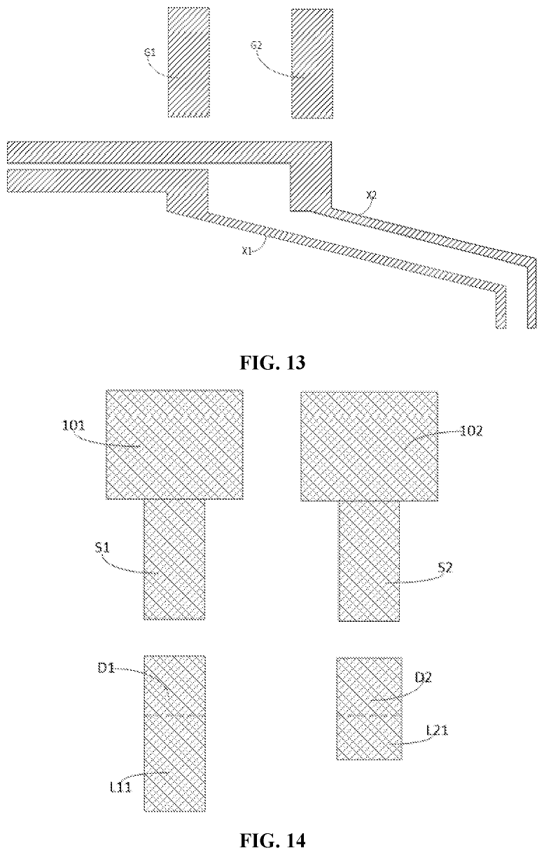

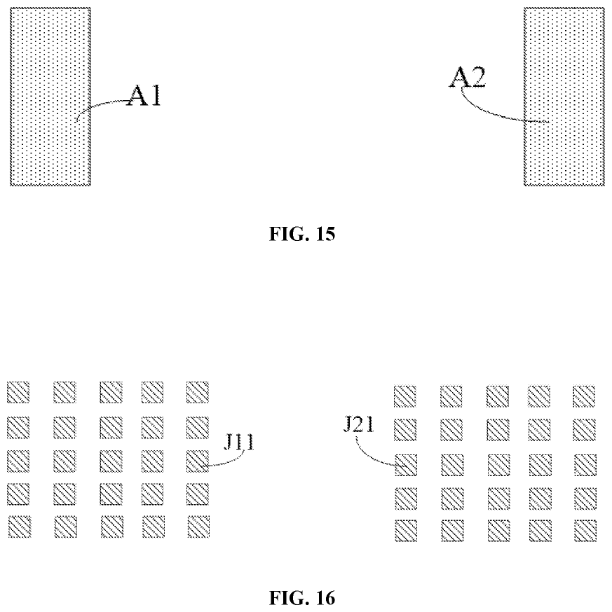

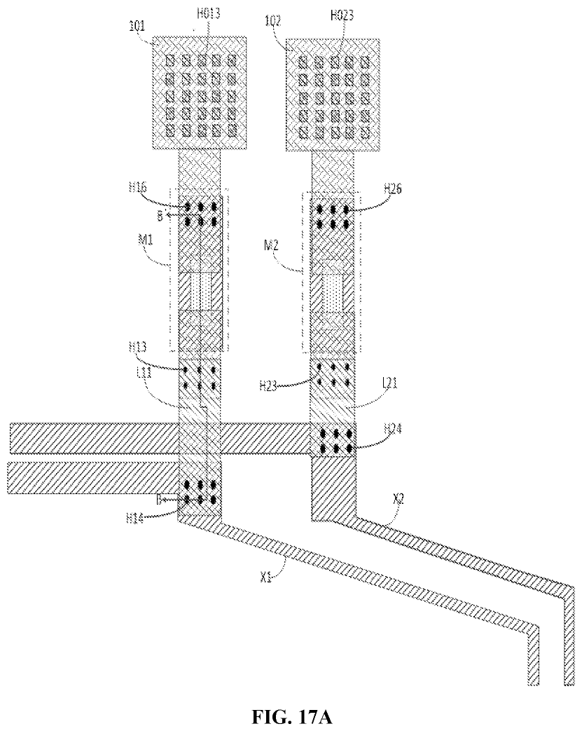

FIG. 13 is a layout diagram of the first metal layer in FIG. 12, FIG. 14 is a layout diagram of the source-drain electrode layer in FIG. 12, FIG. 15 is a layout diagram of the semiconductor layer in FIG. 12, FIG. 16 is a layout diagram of the first conductive layer in FIG. 12. Wherein, the first conductive layer may be an ITO layer.

In FIG. 15, the one labeled A1 is the active pattern of M1, and the one labeled A2 is the active pattern of M2.

As shown in FIGS. 12-16, the first test pad 101 is electrically connected to the first electrode S1 of the first test transistor M1; the second test pad 102 is electrically connected to the first electrode S1 of the second test transistor M2;

The gate electrode G1 of the first test transistor M1 is electrically connected to the first electrode S1 of the first test transistor M1 through the first sixth via hole H16; the gate electrode G2 of the second test transistor M2 is electrically connected to the first electrode S2 of the second test transistor M2 through the second sixth via hole H26;

The second electrode D1 of the first test transistor M1 is electrically connected to the first first connection portion L11; the first first connection portion L11 is connected to the first transmission line X1 through the first seventh via hole H17. The second electrode D2 of the second test transistor M2 is electrically connected to the second first connection portion L21; the second first connection portion L21 is connected to the second transmission line X2 through the second seventh via hole H27.

In at least one embodiment of the present disclosure, the aperture of H16, the aperture of H17, the aperture of H26 and the aperture of H27 may be greater than or equal to 5 μm and less than or equal to 15 μm, but are not limited thereto.

As shown in FIGS. 12 to 16, the first test pad 101 is electrically connected to the first first conductive structure J11 located in the first conductive layer through the first third connection via hole H013. During electrical testing, the electrical test signal can be transmitted to the first test pad 101 through the first first conductive structure J11 and the first third connection via hole H013 through the probe, and then transmitted to the driving circuit, The electrical test signal can be transmitted to the second test pad 102 through the second first conductive structure J21 and the second third connection via hole H023 through a probe, and then transmitted to the driving circuit.

In at least one embodiment of the display substrate shown in FIGS. 12 to 16, when ESD occurs, the first test transistor M1 and the second test transistor M2 are burned out first, thereby protecting the internal units of the GOA from being affected.

Optionally, the aperture of the first third connection via hole H03 may be greater than or equal to 30 μm and less than or equal to 80 μm, and the aperture of the second third connection via hole H023 may be greater than or equal to 30 μm but less than or equal to 80 μm. For example, the aperture of the first third connection via hole H013 may be 40 μm, and the aperture of the second third connection via hole H023 may be 40 μm.

In at least one embodiment of the present disclosure, the resistivity of the first connection portion is greater than the resistivity of the transmission line; the test structure further includes a third electrostatic discharge structure;

The first connection portion is electrically connected to the second electrode through the third electrostatic discharge structure;

The third electrostatic discharge structure includes a plurality of third via holes.

In specific implementation, the first connection portion is electrically connected to the second electrode through a plurality of third via holes included in the third electrostatic discharge structure. By using a plurality of third via holes, compared with using a single third via hole, better electrostatic protection can be provided.

In at least one embodiment of the present disclosure, the test structure further includes a fourth electrostatic discharge structure;

The first connection portion is electrically connected to the transmission line through the fourth electrostatic discharge structure;

The fourth electrostatic discharge structure includes a plurality of fourth via holes.

In specific implementation, the first via hole is electrically connected to the transmission line through a plurality of fourth via holes included in the fourth electrostatic discharge structure. By using a plurality of fourth via holes, compared with using a single fourth via hole, better electrostatic protection are provided.

Optionally, the resistivity of the first connection portion is greater than the resistivity of the transmission line, and the first connection portion is electrically connected to the second electrode of the test transistor through a third via hole. The first connection portion is electrically connected to the transmission line through a fourth via hole;

An aperture of the third via hole is smaller than an aperture of the fourth via hole.

Optionally, the ratio of the aperture of the third via hole to the aperture of the fourth via hole is greater than or equal to 1/1.8 and less than or equal to 1/1.2.

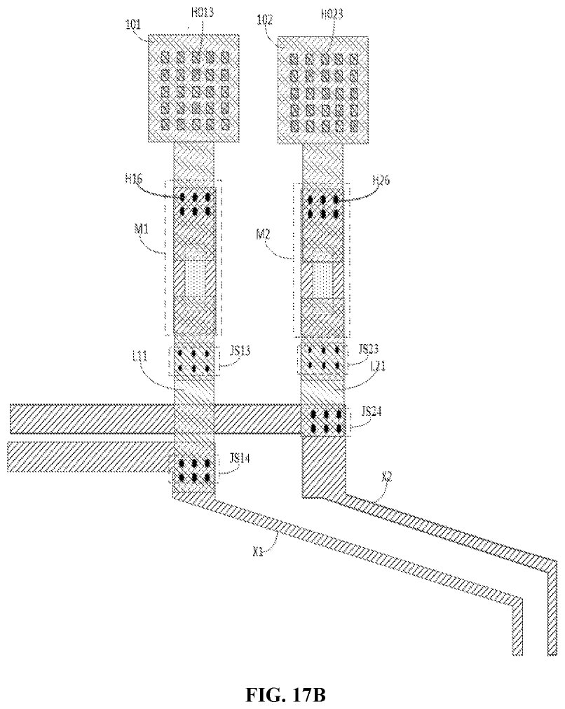

As shown in FIGS. 17A-21, in the display substrate according to at least one embodiment of the present disclosure, the test structure includes an electrical test structure and a first connection portion L1; the electrical test structure includes a first test transistor M1, the second test transistor M2, the first test pad 101 and the second test pad 102; the first test transistor MI is provided on the side of the first transmission line X1 and the second transmission line X2 away from the display area; the second test transistor M2 is provided on the side of the first transmission line X1 and the second transmission line X2 away from the display area;

The first transmission line X1 and the second transmission line X2 are signal transmission lines between the driving integrated circuit and the driving circuit;

The first test transistor M1 includes a gate electrode, a first electrode and a second electrode; the gate electrode G1 of the first test transistor M1 is electrically connected to the first electrode S1 of the first test transistor M1, and the second electrode D1 of the first test transistor M1 is electrically connected to the first transmission line X1 through the first first connection portion L11;

The second test transistor M2 includes a gate electrode, a first electrode and a second electrode; the gate electrode G2 of the second test transistor M2 is electrically connected to the first electrode S2 of the second test transistor M2, and the second electrode D2 of the second test transistor M2 is electrically connected to the second transmission line X2 through the second first connection portion L21.

In at least one embodiment of the display substrate shown in FIGS. 17A to 21, the first transmission line X1, the second transmission line X2, the gate electrode G1 of the first test transistor M1 and the gate electrode G2 of the second test transistor M2 may be located in the first metal layer, the first test pad 101, the second test pad 102, the first electrode S1 of the first test transistor M1, the second electrode D1 of the first test transistor M1, the first electrode S2 of the second test transistor M1 and the second electrode D2 of the second test transistor M2 are located in the second metal layer; the first first connection portion L11 and the second first connection portion L21 are located in the first conductive layer;

The first metal layer may be a gate electrode layer, the second metal layer may be a source-drain electrode layer, and the first conductive layer may be an ITO layer.

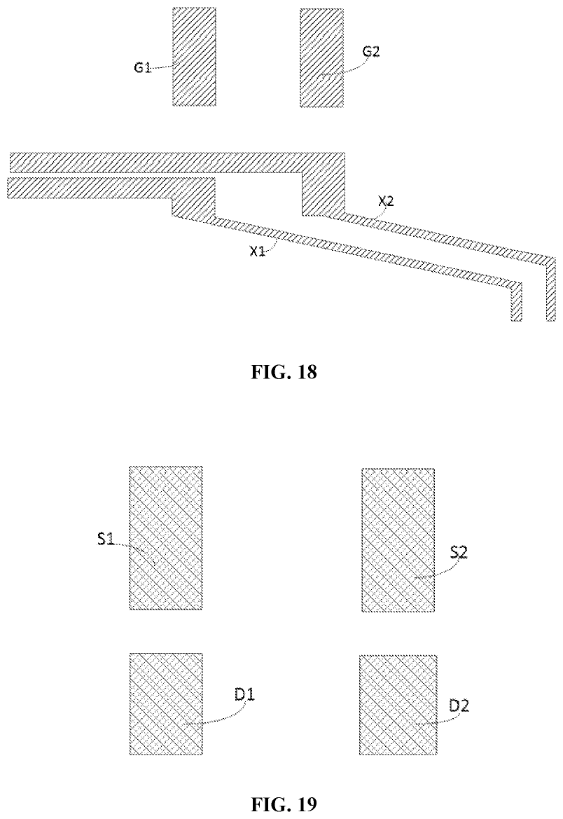

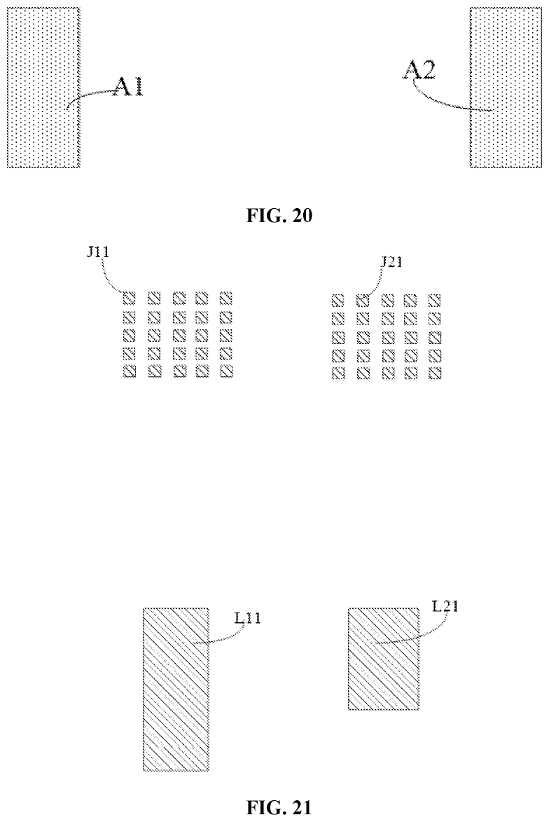

FIG. 18 is a layout diagram of the first metal layer in FIG. 17A. FIG. 19 is a layout diagram of the source-drain electrode layer in FIG. 17A. FIG. 20 is a layout diagram of the semiconductor layer in FIG. 17A. FIG. 21 is a layout diagram of the first conductive layer in FIG. 17A.

In FIG. 20, the one labeled A1 is the active pattern of M1, and the one labeled A2 is the active pattern of M2.

As shown in FIGS. 17A-21, the first test pad 101 is electrically connected to the first electrode S1 of the first test transistor M1;

The gate electrode G1 of the first test transistor M1 is electrically connected to the first electrode S1 of the first test transistor M1 through the first sixth via hole H16;

The second electrode D1 of the first test transistor M1 is electrically connected to the first first connection portion L11 through the first third via hole H13; the first first connection portion L11 is electrically connected to the first transmission line X1 through the first fourth via hole H14;

The gate electrode G2 of the second test transistor M2 is electrically connected to the first electrode S2 of the second test transistor M2 through the second sixth via hole H26;

The second electrode D2 of the second test transistor M2 is electrically connected to the second first connection portion L21 through the second third via hole H23; the second first connection portion L21 is electrically connected to the second transmission line X2 through the second fourth via hole H24.

As shown in FIGS. 17A to 21, the first test pad 101 is electrically connected to the first first conductive structure J11 located in the first conductive layer through the first third connection via hole H013. The second test pad 102 is electrically connected to the second first conductive structure J21 located in the first conductive layer through the second third connection via hole H023. When performing electrical testing, the electrical test signal can be transmitted to the first test pad 101 through the first first conductive structure J11 and the first third connection via hole H013 through the probe, and then to the driving circuit. The electrical test signal can be transmitted to the second test pad 102 through the second first conductive structures J21 and the second third connection via hole H023 through the probe, then to the driving circuit.

In at least one embodiment of the display substrate shown in FIGS. 17A-21, the resistivity of the first first connection portion L11 is greater than the resistivity of the first transmission line X1; the resistivity of the second first connection portion L11 is greater than the resistivity of the second transmission line X2;

The thickness of the first first connection portion L11 is less than the thickness of the first transmission line X1, and the thickness of the second first connection portion L21 is less than the thickness of the second transmission line X2.

In at least one embodiment of the display substrate shown in FIGS. 17A to 21, the resistance of L11 may be greater than the resistance of X1, and the resistance of L21 may be greater than the resistance of X2.

In at least one embodiment of the display substrate shown in FIGS. 17A to 21, the aperture of the first third via hole H13 is smaller than the aperture of the first fourth via hole H14, and the aperture of the second third via hole H13 is smaller than the aperture of the second fourth via hole H24.

In at least one embodiment of the display substrate shown in FIGS. 17A to 21, the aperture of H13 may be greater than or equal to 5 μm and less than or equal to 15 μm, the aperture of H23 may be greater than or equal to 5 μm and less than or equal to 15 μm, and the aperture of H14 may be greater than or equal to 15 μm and less than or equal to 40 μm, the aperture of H24 may be greater than or equal to 15 μm and less than or equal to 40 μm, but is not limited to this.

In at least one embodiment of the display substrate shown in FIGS. 17A to 21, when ESD occurs, the first test transistor M1, the second test transistor M2, the first third via hole H13 and the second third via hole H23 are burned out first, thus protecting the internal units of GOA from being affected.

In at least one embodiment of the display substrate shown in FIGS. 17A to 21, the aperture of H013 and the aperture of H023 may be greater than or equal to 30 μm and less than or equal to 80 μm. For example, the aperture of H013 and the aperture of H023 may be 40 μm, but not limited to this.

In FIG. 17B, the one labeled JS13 is the first third electrostatic release structure, and the one labeled JS23 is the second third electrostatic release structure;

The first third electrostatic discharge structure JS13 includes six third via holes, and the second third electrostatic discharge structure JS23 includes six third via holes;

The first fourth electrostatic discharge structure JS14 includes six fourth via holes, and the second fourth electrostatic discharge structure JS24 includes six fourth via holes.

In at least one embodiment shown in FIGS. 17A to 21, each third electrostatic discharge structure includes six third via holes, and each third electrostatic discharge structure includes six third via holes, so as to provide good electrostatic protection by increasing the number of via holes.

In at least one embodiment shown in FIGS. 17A to 21, the first test pad 101 may be used to transmit a first noise reduction voltage signal VDDO, and the second test pad 102 may be used to transmit a second noise reduction voltage signal VDDE; the first test transistor M1 and the second test transistor M2 may be oxide transistors, and the width-to-length ratio of M1 and the width-to-length ratio of M2 may be less than or equal to 2, but not limited.

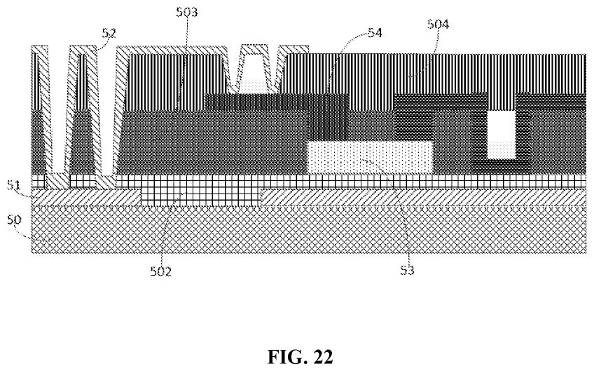

FIG. 22 is a B-B′ cross-sectional view in FIG. 17A.

In FIG. 22, 50 is the base, 51 is the first metal layer, 52 is the first conductive layer, 53 is the semiconductor layer, and 54 is the second metal layer;

502 is the second insulating layer, 503 is the third insulating layer, and 504 is the fourth insulating layer.

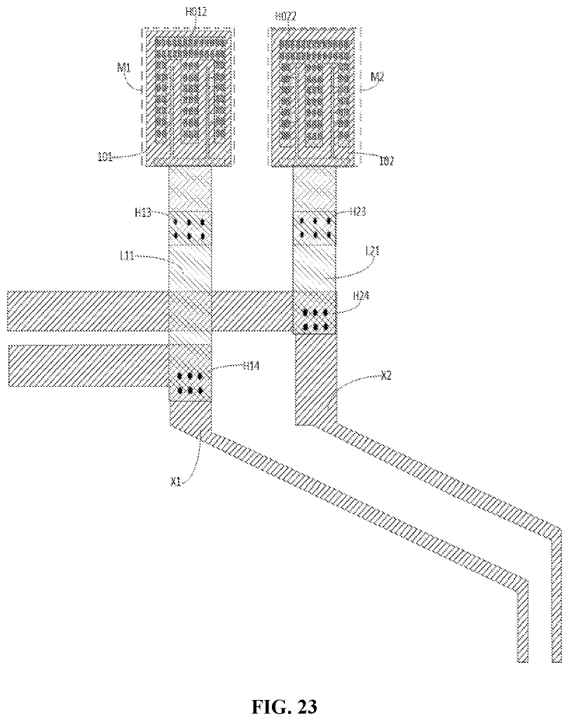

As shown in FIGS. 23-27, in the display substrate according to at least one embodiment of the present disclosure, the test structure includes an electrical test structure, a first first connection portion L11 and a second first connection portion L21; The electrical test structure includes a first test transistor M1 and a second test transistor M2; the first test transistor M1 is arranged on a side of the first transmission line X1 and the second transmission line X2 away from the display area. The second test transistor M2 is provided on the side of the first transmission line X1 and the second transmission line X2 away from the display area;

The first transmission line X1 and the second transmission line X2 are signal transmission lines between the driving integrated circuit and the driving circuit;

The first test transistor M1 includes a gate electrode, a first electrode and a second electrode; the gate electrode of the first test transistor M1 is electrically connected to the first electrode S1 of the first test transistor M1, and the second electrode D1 of the first test transistor M1 is electrically connected to the first transmission line X1 through the first first connection portion L11;

The second test transistor M2 includes a gate electrode, a first electrode and a second electrode; the gate electrode of the second test transistor M2 is electrically connected to the first electrode S2 of the second test transistor M2, and the second electrode D2 of the second test transistor M2 is electrically connected to the second transmission line X2 through the second first connection portion L21;

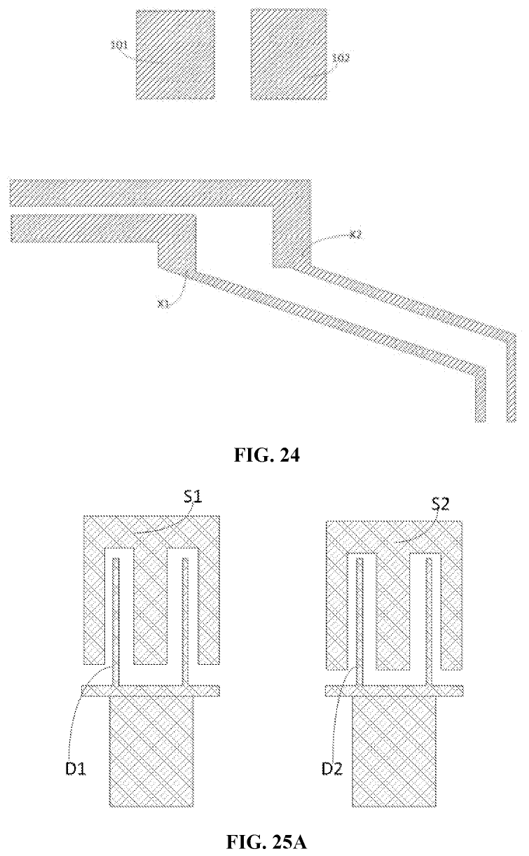

As shown in FIG. 24, the gate electrode of the first test transistor M1 and the first test pad 101 have an integrated structure, and the gate electrode of the second test transistor M2 and the second test pad 102 have an integrated structure;

The first test transistor M1 is used to transmit electrical test signals to the first transmission line X1, and the second test transistor M2 is used to transmit electrical test signals to the second transmission line X2.

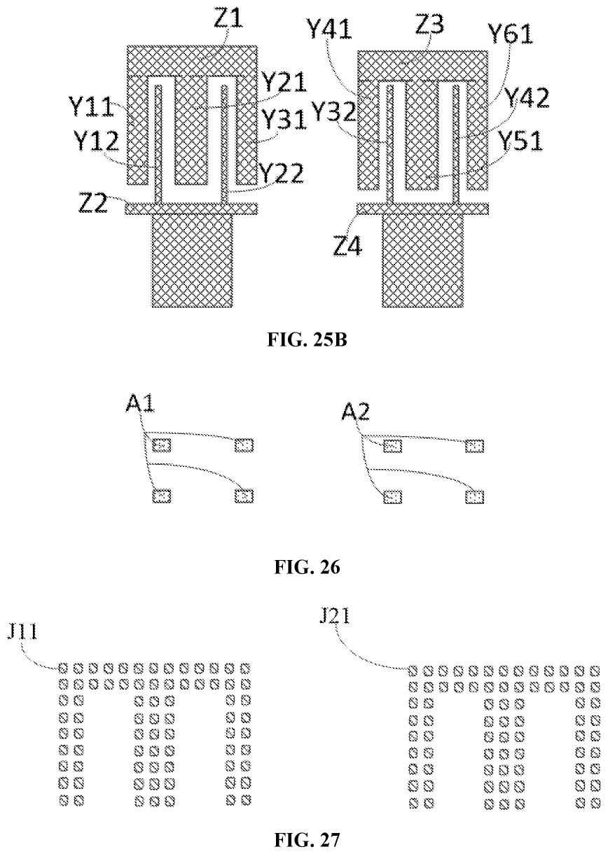

In FIG. 25A, the one labeled S1 is the first electrode of M1, the one labeled D1 is the second electrode of M1; the one labeled S2 is the first electrode of M2, and the one labeled D2 is the second electrode of M2.

In at least one embodiment shown in FIGS. 23 to 27, the first transmission line X1, the second transmission line X2, the first test pad 101 and the second test pad 102 are all located in the first metal layer, the first electrode S1 of the first test transistor M1, the second electrode D1 of the first test transistor M1, the first electrode S2 of the second test transistor M2 and the second electrode D2 of the second test transistor M2 are located in the second metal layer, and the first first connection portion L11 and the second first connection portion L21 are located in the first conductive layer;

The first metal layer may be a gate electrode layer, and the second metal layer may be a source-drain electrode layer, but is not limited thereto.

FIG. 24 is a layout diagram of the first metal layer in FIG. 23. FIGS. 25A and 25B are a layout diagram of the second metal layer in FIG. 23. FIG. 26 is a layout diagram of the semiconductor layer in FIG. 23. FIG. 27 is a layout diagram of the first conductive layer in FIG. 23.

In FIG. 26, the one labeled A1 is the active pattern of M1, and the one marked A2 is the active pattern of M2.

As shown in FIGS. 23 to 27, the second electrode D1 of the first test transistor M1 is electrically connected to the first first connection portion L11 through the first third via H13, and the second electrode D2 of the second test transistor M2 is electrically connected to the second first connection portion L21 through the second third via hole H23;

The first first connection portion L11 is electrically connected to the first transmission line X1 through the first fourth via hole H14; the second first connection portion L21 is electrically connected to the second transmission line X2 through the second fourth via hole H24;

The first test pad 101 is electrically connected to the first electrode S1 of the first test transistor M1 and the first first conductive structure J11 located in the first conductive layer through the first second connection via hole H012; the second test pad 102 is respectively connected to the first electrode S2 of the second test transistor M2 and the second first conductive structure located in the first conductive layer J21 through the second second connection via hole H022.

The aperture of the first second connection via hole H012 may be greater than or equal to 30 μm and less than or equal to 80 μm, and the aperture of the second second connection via hole H022 may be greater than or equal to 30 μm and less than or equal to 80 μm, for example, the aperture of the first second connection via hole H012 may be 40 μm, and the aperture of the second second connection via hole H022 may be 40 μm.

In at least one embodiment shown in FIGS. 23 to 27, the first test transistor M1 and the second test transistor M2 may be n-type transistors, but are not limited thereto.

In at least one embodiment of the display substrate shown in FIGS. 23-27, the resistivity of the first first connection portion L11 is greater than the resistivity of the first transmission line X1; the resistivity of the second first connection portion L21 is greater than the resistivity of the second transmission line X2;

The thickness of the first first connection portion L11 is less than the thickness of the first transmission line X1, and the thickness of the second first connection portion L21 is less than the thickness of the second transmission line X2.

In at least one embodiment of the display substrate shown in FIGS. 23 to 27, the resistance of L11 may be greater than the resistance of X1, and the resistance of L21 may be greater than the resistance of X2.

In at least one embodiment of the display substrate shown in FIGS. 23 to 27, the aperture of the first third via hole H13 is smaller than the aperture of the first fourth via hole H14, and the aperture of the second third via hole H13 is smaller than the aperture of the second fourth via hole H24.

In at least one embodiment of the display substrate shown in FIGS. 23 to 27, the aperture of H13 may be greater than or equal to 5 μm and less than or equal to 15 μm, the aperture of H23 may be greater than or equal to 5 μm and less than or equal to 15 μm, and the aperture of H14 may be greater than or equal to 15 μm and less than or equal to 40 μm, the aperture of H24 may be greater than or equal to 15 μm and less than or equal to 40 μm, but is not limited to this.

In at least one embodiment shown in FIGS. 23 to 27, the electrical test structure includes a diode-connected first test transistor M1 and a diode-connected second test transistor M2. The gate electrode of the first test transistor M1 is multiplexed as the first test pad 101, the gate electrode of the second test transistor M2 is multiplexed as the second test pad 102. When ESD passes through, the first test transistor M1, the second test transistor M2, the first third via hole H13 and the second third via hole H23 is burned out first, forming a short circuit to protect the GOA circuit.

In at least one embodiment shown in FIGS. 23 to 27, the first test pad 101 may be used to transmit the first noise reduction voltage signal VDDO, and the second test pad 102 may be used to transmit the second noise reduction voltage signal VDDE;

In specific implementation, when the potential of VDDO is a high voltage, the first test transistor M1 is turned on and VDDO is transmitted into the display panel. At this time, the potential of VDDE is a low voltage, the second test transistor M2 is turned off, and the GOA circuit operates normally; when the potential of VDDO is a low voltage, the first test transistor M1 is turned off. At this time, the potential of VDDE is a high voltage, the second test transistor M2 is turned on, and VDDE is transmitted into the display panel, and the GOA circuit works normally;

When ESD occurs, the ESD first passes through the first test transistor M1 and the second test transistor M2. The first test transistor M1 and the second test transistor M2 are burned out, thereby protecting the GOA circuit and preventing the problem of conductorization of transistors included in the noise reduction unit caused by ESD impact, optimizing display product design and improving display product life.

As shown in FIGS. 25A and 25B, the first electrode S1 of the first test transistor M1 includes a first body portion Z1 extending in the horizontal direction and a first first extension portion Y11 extending in the vertical direction, the second first extension portion Y21 extending in the vertical direction and the third first extension portion Y31 extending in the vertical direction that are electrically connected to each other;

Y11, Y21 and Y31 are arranged in the horizontal direction;

The second electrode D1 of the first test transistor M1 includes a second body portion Z2 extending in the horizontal direction, a first second extension portion Y12 extending in the vertical direction, and a second second extension portion Y22 in the vertical direction that are electrically connected to each other.

Y12 and Y22 extend in the horizontal direction;

Y12 is set between Y11 and Y21, Y12 is set between Y21 and Y31;

The second electrode S2 of the second test transistor M1 includes a third body portion Z3 extending in the horizontal direction, a fourth first extension portion Y41 extending in the vertical direction, and a fifth first extension portion Y51 extending in the vertical direction and a sixth first extension portion Y61 extending in the vertical direction that are electrically connected to each other.

Y41, Y51 and Y61 are arranged in the horizontal direction;

The second electrode D2 of the second test transistor M2 includes a fourth body portion Z4 extending in the horizontal direction, a third second extension portion Y32 extending in the vertical direction, and a fourth second extension portion Y42 in the vertical direction that are electrically connected to each other.

Y32 and Y42 extend in the horizontal direction;

Y32 is set between Y41 and Y51, and Y42 is set between Y51 and Y61.

In at least one embodiment of the present disclosure, the test pad and the transmission line may both be located in the same conductive layer, and the transmission line and the first connection portion may be located in different conductive layers.

For example, the test pad and the transmission line may both be located in the first metal layer, and the first connection portion may be located in the first conductive layer.

Optionally, the first connection portion, the first electrode and the second electrode are located in the same conductive layer, the gate electrode and the transmission line are located in the same conductive layer, the first connection portion and the transmission line are located in a different conductive layers.

For example, the first connection portion, the first electrode and the second electrode may all be located in the second metal layer, the gate electrode and the transmission line may all be located in the first metal layer, and the first connection portion may be located in the first conductive layer.

In at least one embodiment of the present disclosure, the first electrode and the second electrode are located in the same conductive layer, the gate electrode and the transmission line are located in the same conductive layer, and the first connection portion and the first electrode are located in different conductive layers, and the first connection portion and the transmission line are located in different conductive layers.

For example, the first electrode and the second electrode may both be located in the second metal layer, the gate electrode and the transmission line may both be located in the first metal layer, and the first connection portion may be located in the first conductive layer.

Optionally, the test pad, the first electrode, the second electrode and the first connection portion are located in the same conductive layer, the gate electrode and the transmission line are located in the same conductive layer, and the first connection portion and the transmission line are located in different conductive layers.

For example, the test pad, the first electrode, the second electrode and the first connection portion may all be located in the second metal layer, and the gate electrode and the transmission line may all be located in the first metal layer, the first connection portion may be located in the first conductive layer.

Optionally, the test pad, the first electrode and the second electrode are located in the same conductive layer, the gate electrode and the transmission line are located in the same conductive layer, and the first connection portion and the test pads are located in different conductive layers, and the first connection portion and the transmission line are located in different conductive layers.

For example, the test pad, the first electrode and the second electrode may all be located in the second metal layer, the gate electrode and the transmission line may all be located in the first metal layer, and the first connection portion may be located in the first conductive layer.

The display substrate described in at least one embodiment of the present disclosure can burn the test transistor and/or the first connection portion when ESD occurs without increasing additional development costs and the number of masks, ensuring that the GOA circuit in the display panel is not affected by ESD, thereby extending the life of the display product.

The embodiments can effectively improve the anti-static capability of display products without occupying additional space, without affecting the wiring of display products, without increasing the border design, without increasing the number of Masks, and thereby improving the competitiveness of display products.

The display panel according to the embodiment of the present disclosure includes a driving integrated circuit and the above-mentioned test structure;

The driving integrated circuit is used to provide signals to the driving circuit.

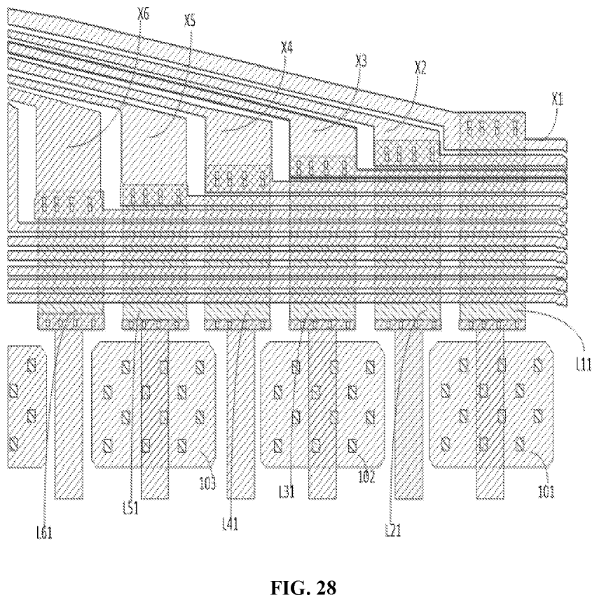

FIG. 28 is a schematic diagram of a test structure included in a display panel according to at least one embodiment of the present disclosure.

In FIG. 28, the one labeled X1 is the first transmission line, the one labeled X2 is the second transmission line, the one labeled X3 is the third transmission line, and the one labeled X4 is the fourth transmission line. The one labeled X5 is the fifth transmission line, the one labeled X6 is the sixth transmission line, the one labeled 101 is the first test pad, the one labeled 102 is the second test pad, and the one labeled 103 is the third test pad. The one labeled L11 is the first first connection portion, the one labeled L21 is the second first connection portion, the one labeled L31 is the third first connection portion, and the one labeled L41 is the fourth first connection portion, the one labeled L51 is the fifth first connection portion, and the one labeled L61 is the sixth first connection portion;

L11 is electrically connected to X1, L21 is electrically connected to X2, L31 is electrically connected to X3, L41 is electrically connected to X4, L51 is electrically connected to X5, and L61 is electrically connected to X6;

The first test pad 101 is electrically connected to L11, the second test pad 102 is electrically connected to L31, and the third test pad 103 is electrically connected to L51.

In the schematic diagram of the test structure shown in FIG. 28, the left side of each transmission line is the driving circuit inside the display panel.

The display device according to the embodiment of the present disclosure includes the above-mentioned display panel.

The above descriptions are implementations of the present disclosure. It should be pointed out that those skilled in the art can make some improvements and modifications without departing from the principle of the present disclosure. These improvements and modifications shall also fall within the scope of the present disclosure.

1. A display substrate having a display area and a peripheral area, wherein the display substrate includes a test structure, a transmission line and a driving circuit; the test structure includes an electrical test structure and a first connection portion;
the electrical test structure is arranged on a side of the transmission line away from the display area; the electrical test structure is configured to transmit an electrical test signal to the driving circuit; the driving circuit is configured to provide a driving signal;
the transmission line is a signal transmission line between a driving integrated circuit and the driving circuit; the electrical test structure is electrically connected to the transmission line through the first connection portion;
the transmission line and the first connection portion are located in different conductive layers.

2. The display substrate according to claim 1, wherein a resistivity of the first connection portion is greater than a resistivity of the transmission line.

3. The display substrate according to claim 1, wherein the electrical test structure includes a test transistor; the test transistor includes a gate electrode, a first electrode and a second electrode; the gate electrode is electrically connected to the first electrode, and the second electrode is electrically connected to the transmission line through the first connection portion.

4. The display substrate according to claim 1, wherein the transmission line is a single-layer line, and the first connection portion is a single-layer connection portion.

5. The display substrate according to claim 2, wherein the electrical test structure includes a test pad;
the test pad is electrically connected to the first connection portion.

6. The display substrate according to claim 5, wherein the test structure further includes a first electrostatic discharge structure;
the first connection portion is electrically connected to the test pad through the first electrostatic discharge structure;
the first electrostatic discharge structure includes a plurality of first via holes.

7. The display substrate according to claim 5, wherein the test structure further includes a second electrostatic discharge structure;
the first connection portion is electrically connected to the transmission line through the second electrostatic discharge structure;
the second electrostatic discharge structure includes a plurality of second via holes.

8. The display substrate according to claim 5, wherein the first connection portion is electrically connected to the test pad through a first via hole, and the first connection portion is electrically connected to the transmission line through a second via hole;
an aperture of the first via hole is smaller than an aperture of the second via hole;
wherein a ratio of the aperture of the first via hole to the aperture of the second via hole is greater than or equal to 1/1.8 and less than or equal to 1/1.2.

9. (canceled)

10. The display substrate according to claim 3, wherein the electrical test structure further includes a test pad; the gate electrode of the test transistor and the test pad form an integral structure; the test transistor is configured to transmit an electrical test signal to the transmission line;
or
wherein the electrical test structure further includes a test pad; the test pad is configured to transmit an electrical test signal to the test transistor; the gate electrode of the test transistor and the test pad are separate structures;
the first electrode is electrically connected to the test pad.

11. (canceled)

12. The display substrate according to claim 10, wherein a resistivity of the first connection portion is greater than a resistivity of the transmission line; the test structure further includes a third electrostatic discharge structure;
the first connection portion is electrically connected to the second electrode through the third electrostatic discharge structure;
the third electrostatic discharge structure includes a plurality of third via holes;
or
wherein the test structure further includes a fourth electrostatic discharge structure;
the first connection portion is electrically connected to the transmission line through the fourth electrostatic discharge structure;
the fourth electrostatic discharge structure includes a plurality of fourth via holes.

13. (canceled)

14. The display substrate according to claim 10, wherein a resistivity of the first connection portion is greater than a resistivity of the transmission line, and the first connection portion is electrically connected to the second electrode through a third via hole, and the first connection portion is electrically connected to the transmission line through a fourth via hole;
an aperture of the third via hole is smaller than an aperture of the fourth via hole;
wherein a ratio of the aperture of the third via hole to the aperture of the fourth via hole is greater than or equal to 1/1.8 and less than or equal to 1/1.2.

15. (canceled)

16. The display substrate according to claim 1, wherein a thickness of the first connection portion is smaller than a thickness of the transmission line;
or
wherein the first connection portion is located in a first conductive layer, and the first conductive layer is made of ITO.

17. (canceled)

18. The display substrate according to claim 3, wherein the test transistor is an oxide transistor, and a width-to-length ratio of the test transistor is less than or equal to 2;
or
the test transistor is an amorphous silicon transistor, and a width-to-length ratio of the test transistor is less than or equal to 100/3.6.

19. (canceled)

20. The display substrate according to claim 5, wherein the test pad and the transmission line are located in a same conductive layer, and the transmission line and the first connection portion are located in different conductive layers.

21. The display substrate according to claim 10, wherein the first connection portion, the first electrode and the second electrode are located in a same conductive layer, and the gate electrode and the transmission line are located in a same conductive layer, the first connection portion and the transmission line are located in different conductive layers.

22. The display substrate according to claim 10, wherein the first electrode and the second electrode are located in a same conductive layer;
the first electrode includes a first body portion and at least one first extension portion that are electrically connected to each other, and the second electrode includes a second body portion and at least one second extension portion;
the first body portion and the second body portion both extend along a first direction, and the first extension portion and the second extension portion both extend along a second direction;
the first direction intersects the second direction;
wherein the first electrode includes at least two first extension portions, and the at least two first extension portions are arranged along the first direction;
the second electrode includes at least two second extension portions, the at least two second extension portions are arranged along the first direction;
at least part of at least one second extension portion is arranged between two adjacent first extension portions.

23. (canceled)

24. The display substrate according to claim 10, wherein the first electrode and the second electrode are located in a same conductive layer, the gate electrode and the transmission line are located in a same conductive layer, and the first connection portion and the first electrode are located in different conductive layers, and the first connection portion and the transmission line are located in different conductive layers.

25. The display substrate according to claim 11, wherein the test pad, the first electrode, the second electrode and the first connection portion are located in a same conductive layer, and the gate electrode and the transmission line are located in a same conductive layer, and the first connection portion and the transmission line are located in different conductive layers;
or
wherein the test pad, the first electrode and the second electrode are located in a same conductive layer, and the gate electrode and the transmission line are located in a same conductive layer, the first connection portion and the test pad are located in different conductive layers, and the first connection portion and the transmission line are located in different conductive layers.

26. (canceled)

27. A display panel, comprising the driving integrated circuit and the display substrate according to claim 1;
the driving integrated circuit is configured to provide a signal to the driving circuit.

28. A display device, comprising the display panel according to claim 27.
